(19) United States
(12) Patent Application Publication
(10) Pub. No.: US 2026/0024718 A1
(43) Pub. Date: Jan. 22, 2026

(54) HIGH TEMPERATURE NV CENTER SENSING UP TO 1400K

(71) Applicant: The Chinese University of Hong Kong, Hong Kong (CN)

(72) Inventors: Ren-Bao LIU, Hong Kong (CN); Quan LI, Hong Kong (CN); Jing-Wei FAN, Hefei (CN); Shuai-Wei GUO, Hong Kong (CN)

(21) Appl. No.: 19/269,898

(22) Filed: Jul. 15, 2025

Related U.S. Application Data
(60) Provisional application No. 63/672,296, filed on Jul. 17, 2024.

(51) Int. Cl. H01J 37/295; H01J 37/26

(52) U.S. Cl. CPC H01J 37/295; H01J 37/261; H01J 2237/0817; H01J 2237/2065; H01J 2237/2802

(57) ABSTRACT

A method for fast laser heating and cooling for nano/micro diamond is provided. The method includes performing laser irradiation and thermal dissipation on a reduced graphene oxide (rGO) sample. The rGO sample is dispersed on transmission electron microscopy (TEM) copper grids and nanodiamonds containing nitrogen-vacancy (NV) centers are dispersed on the rGO sample. The rGO sample is placed in a vacuum chamber and NV spins are polarized and read out by green laser. Further, the spin states of NV spins are manipulated by microwave. The polarizing and reading out are conducted at room temperature, while the manipulating spin states is conducted at high temperatures. The heating and cooling rates are significantly improved using reduced graphene oxide as the laser absorber and heat drain, enabling coherent quantum operation at temperatures up to 1400 Kelvin, surpassing the Curie temperatures of all known magnetic materials.

### CROSS-REFERENCE TO RELATED APPLICATION

This application claims the benefit of U.S. Patent Application Ser. No. 63/672,296, filed Jul. 17, 2024, which is hereby incorporated by reference in its entirety including any tables, figures, or drawings.

### BACKGROUND OF THE INVENTION

Quantum coherence control at high temperature is fundamentally important for advancing the quantum world and is practically useful for applying quantum technologies, such as quantum sensing, to realistic environments and materials.

Researchers have demonstrated the quantum control of nitrogen-vacancy spins in diamond at temperatures up to 1000 Kelvin. This was achieved by polarizing and reading out the spins at room temperature and then controlling them at elevated temperatures using rapid heating and cooling. Extending the working temperature range is desirable for applications to a broader range of materials but is limited by the fast spin relaxation at high temperatures compared to the heating and cooling rates.

The preservation and control of quantum coherence usually requires well-isolated systems under stringent conditions such as low temperatures. Demonstration of quantum coherence control in harsh environments, such as high temperatures, is not only intriguing for addressing the fundamental question about the boundary between the quantum and classical worlds but also useful for real-life application of quantum technologies, such as quantum sensing study of materials for practical uses.

An outstanding example of quantum coherence is the nitrogen-vacancy (NV) center spins in diamond, which can be prepared, detected, and controlled under ambient conditions, high pressure, and in liquids. The continuous-wave optically detected magnetic resonance (ODMR) of NV spins persists at temperatures up to 700 K¹. Recently, by using rapid heating and cooling of nano-systems, it has been demonstrated that NV spins in a nanodiamond (ND) can be initialized at room temperature, then coherently controlled to perform quantum sensing (for example, nano-magnetometry) at high temperatures, and finally read out at room temperature.

Such high-temperature quantum control and quantum sensing can facilitate the research of a broad range of thermal phenomena, including magnetic transitions², magneto-structural transitions³⁻⁴, thermoremanent magnetism in rock particles⁵, thermo-plasmonic of nanopartciles⁶⁻⁷, heat-assisted magnetic recording⁸⁻⁹, thermal management using two-dimensional materials¹⁰.

The previous work on high-temperature quantum coherence control has been limited to about 1000 Kelvin, due to the rapid spin relaxation at high temperature (˜5 μs at about 1000 K), which is comparable to the heating and cooling time (˜2 μs). Extending the working temperature range is desirable for applications to a broader range of material systems and can enable in-situ investigation of the NV dynamics in NDs.

### BRIEF SUMMARY OF THE INVENTION

There continues to be a need in the art for improved designs and techniques for a method for high temperature NV center sensing up to 1400 K.

According to an embodiment of the subject invention, a method for fast laser heating and cooling for nano/micro diamond is provided. The method comprises performing laser irradiation and thermal dissipation on a reduced graphene oxide (rGO) sample, wherein the rGO sample is dispersed on transmission electron microscopy (TEM) copper grids. The method may further comprise dispersing nanodiamonds (NDs) containing nitrogen-vacancy (NV) centers on the rGO sample. The method may further comprise placing the rGO sample in a vacuum chamber. The method may further comprise polarizing and reading out NV spins by green laser. The method may further comprise manipulating spin states of NV spins by microwave. The polarizing and reading out are conducted at room temperature. Further, the manipulating spin states is conducted at elevated temperatures higher than 300 K. After polarizing of the NV center spins, the NDs are heated to a stationary temperature by a pulse of 850 nm near-infrared (NIR) laser with a duration of 2000 ns. The method may further comprise applying a microwave pulse of duration 40 ns for pulsed-ODMR measurement at different times in the heating and cooling stages.

### BRIEF DESCRIPTION OF THE DRAWINGS

FIGS. 1A-1E show heating and cooling dynamics of nanodiamonds on reduced graphene oxide dropped on a copper grid, wherein FIG. 1A is a TEM image of an ND located on rGO deposited on a copper grid with amorphous carbon films, the background shadows result from the uneven thickness of rGO, FIG. 1B shows pulse sequence for characterizing the heating and cooling dynamics, including a 532 nm laser pulse with duration of 5 μs for spin polarization (P) and readout (R), an 850 nm NIR laser pulse (τ_{NIR}=2 μs) for heating (H), and a microwave π-pulse of 40 ns for spin control, wherein the cooling time between H and R is set as 2000 ns, FIGS. 1C and 1D are plot diagrams showing ODMR spectra of an ND with the π pulse applied at various times, with t ranging (FIG. 1C) from 0 to 2000 ns (t≤τ_{NIR}), covering the heating process and (FIG. 1D) from 2000 to 4000 ns (t≥τ_{NIR}), covering the cooling process, wherein FIG. 1E is a plot diagram showing temperature as a function of time, the two flat stages (with duration ta) are due to the AOM delay in applying the NIR pulse and the time needed for heat diffusion from the heating spot to the ND, according to an embodiment of the subject invention.

FIGS. 2A-2D show high-temperature ODMR of NV centers in NDs, wherein FIG. 2A shows pulse sequence for HiT-ODMR, the spins are polarized and read out by a green laser pulse (P) of duration 5 μs, the NIR heating pulse (H) is set to be 2.5 μs long, the cooling time is set as 2.5 μs, the NIR laser power is tuned to heat the NDs to various temperatures, a microwave pulse of duration 34 ns is applied at the end of the NIR pulse to measure ODMR, wherein FIG. 2B is an ODMR spectra of two NDs (ND3 and ND68) for various temperatures, wherein FIG. 2C shows the zero-field splitting D vs temperature T for eight NDs, in comparison with the previous results in Ref. 14 and Ref. 1, the brown curve is a third-order polynomial fitting of the D-T relationship above 700K, the error bars correspond to the uncertainties of extrapolation fitting the exponential cooling, wherein FIG. 2D shows contrast of the HIT-ODMR spectra measured at different temperatures (blue symbols) and numerical estimation obtained by solving the rate equation of spin relaxation (purple line), according to an embodiment of the subject invention.

FIGS. 3A-3C show temperature-dependence of NV spin relaxation in a nanodiamond (ND3), wherein FIG. 3A shows two-unit pulse sequence for measuring the spin depolarization after a certain relaxation time (tᵣ), each unit is composed of a 5 μs green laser pulse applied at room temperature, then an NIR laser heating pulse (of duration 2.5 μs+tᵣ, with or without a 34 ns microwave π pulse applied at 2.5 μs), and a fixed cooling period (2.5 μs) (after which the NV center spins are read out at room temperature, denoted as R_{1/2} in the green pulses), the difference between the photon counts with and without the microwave π pulse, normalized to the fluorescence recorded during a 500 ns period (denoted as REF in the green pulses), is measured as the spin polarization signal, wherein FIG. 3B shows spin polarization signals as a function of relaxation time tᵣ under near zero field for different temperatures, wherein in FIG. 3C, right axis is spin relaxation rate (1/T₁) of NV spins in the ND as a function of temperature T, the solid red circles are measured without applying a magnetic field and fitted by

$${T}_{1}^{- 1} = {Γ}_{0} + A * {T}^{5}$$

with Γ₀=7.94 (±0.42)×10⁻³ μs⁻¹ and A=3.063 (±0.084)×10⁻¹⁶ μs⁻¹ K⁻⁵, the solid blue circles are measured with a 104 Gauss magnetic field applied to lift the degeneracy between the four crystallographic NV orientations, the blue circles are fitted by

$${T}_{1}^{- 1} = A \times {T}^{5}$$

with A=3.157 (±0.103)×10⁻¹⁶ μs⁻¹ K⁻⁵, blue/red squares are stretched parameter p as a function of T with/without the magnetic field (axis on the left), the error bars are standard fitting errors, according to an embodiment of the subject invention.

FIGS. 4A-4D show Rabi oscillations of NV center spins at high temperatures, wherein FIG. 4A shows pulse sequence, in the first/second unit, the signal/reference photocount Rin was taken during the first 0.5 μs of the 5 μs 532 nm laser pulse with/without a microwave pulse (MW) applied at the latter stage of the heating pulse (H), wherein FIG. 4B shows normalized photon counts (R₁/R₂) as functions of the microwave pulse duration, demonstrating Rabi oscillations of NV center spins, the data for temperatures below 1200 K are collected from ND3, and those above 1200K are from ND61, an external magnetic field (103 Gauss) is applied to lift the degeneracy of the 4 crystallographic NV orientations, and the microwave pulse is set resonant with the NV centers that have the largest splitting when being aligned the best with the magnetic field), wherein FIG. 4C shows temperature dependence of

$${T}_{2}^{*} ,$$

and wherein FIG. 4D shows decay time of Rabi oscillation from experiments and estimated from

$${T}_{2}^{*}$$

as functions of temperature, the error bar is from fitting error, according to an embodiment of the subject invention.

FIGS. 5A-5D. FIG. 5A shows T₁ relaxation of NV centers in a nanodiamond (ND3) at room temperature but with different degeneracy in transition frequencies of four orientation NVs, wherein degeneracy denotes a number of orientations of NV centers with same transition frequency, by manipulating external magnetic field, different degeneracy states are obtained: FIG. 5B shows the results when degeneracy=1, the corresponding magnetic field is also used for T₁ measurement; FIG. 5C shows the results when degeneracy is between 1 and 2; and FIG. 5D shows the results when degeneracy=2, wherein the results when degeneracy=4 are obtained under near-zero filed, wherein A, B, C, D stand for ODMR dips contributed from NV centers of four orientations, according to an embodiment of the subject invention.

FIGS. 6A-6D. FIG. 6A shows the temperature of a nanodiamond (ND17) as a function of time t for various NIR laser powers, the solid symbols are temperatures below 700 K, which are obtained from D-T relationship in reference¹, by extrapolation of exponentially cooling curve, the temperature immediately after the heating pulse is obtained (open symbols), and FIGS. 6B-6D show ODMR spectra for curves I-III, respectively, according to an embodiment of the subject invention.

FIG. 7 is a plot diagram showing the D-T relationship during the ZFS range of 2760 MHz-2815 MHz, calibrated with two nanodiamonds (ND17 and ND18), the D-T relationship in previously published work¹⁴ is also plotted here, wherein the relationship is fitted with a 3-rd polynomial formula:

$$T = 7090795.9855 \; 571 - 764 \; 9.4179 \; 047633 * D + 2.7527387 \; 858147 * {D}^{2} - 3.3040764833069 E - 4 * {D}^{3} ,$$

according to an embodiment of the subject invention.

FIGS. 8A-8D. FIG. 8A shows the temperature of a nanodiamond (ND29) as a function of time t for various NIR laser powers, the solid symbols are temperatures below 700K, which are obtained from D-T relationship in reference¹, by extrapolation of exponentially cooling curve, the temperature immediately after the heating pulse is obtained (open symbols), and FIGS. 8B-8D are ODMR spectra for curves I-III, respectively, according to an embodiment of the subject invention.

FIG. 9 is a plot diagram showing the D-T relationship during the ZFS range of 2700 MHz-2760 MHz, calibrated with three nanodiamonds (ND17, ND26, ND29), the relationship is fitted with a second order polynomial formula:

$$T = 37800.168062 \; 112 - 21. 523024 \; 636337 * D + 0.002965034 \; 496269 * {D}^{2} ,$$

according to an embodiment of the subject invention.

FIGS. 10A-10C. FIG. 10A shows the temperature of a nanodiamond (ND35) as a function of time t for various NIR laser powers, the solid symbols are temperatures below 700K, which are obtained from the D-T relationship in reference [1], by extrapolation of exponentially cooling curve, the temperature immediately after the heating pulse is obtained (open symbols), and FIGS. 10B-10C are ODMR spectra for curves I-II, respectively, according to an embodiment of the subject invention.

FIGS. 11A-11B. FIG. 11A shows a pulse sequence for high temperature T₂* measurement and FIG. 11B shows decay curve of

$${T}_{2}^{*}$$

measured at various temperatures, according to an embodiment of the subject invention.

### DETAILED DISCLOSURE OF THE INVENTION

Embodiments of the subject invention are directed to a method for fast laser heating and cooling for nano/micro diamond by performing laser irradiation and thermal dissipation on a reduced graphene oxide (rGO) sample.

The terminology used herein is for the purpose of describing particular embodiments only and is not intended to be limiting of the invention. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one having ordinary skill in the art to which this invention pertains. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

When the term “about” is used herein, in conjunction with a numerical value, it is understood that the value can be in a range of 90% of the value to 110% of the value, i.e. the value can be +/−10% of the stated value. For example, “about 1 kg” means from 0.90 kg to 1.1 kg.

In describing the invention, it will be understood that a number of techniques and steps are disclosed. Each of these has individual benefits and each can also be used in conjunction with one or more, or in some cases all, of the other disclosed techniques. Accordingly, for the sake of clarity, this description will refrain from repeating every possible combination of the individual steps in an unnecessary fashion. Nevertheless, the specification and claims should be read with the understanding that such combinations are entirely within the scope of the invention and the claims.

According to the embodiments of the subject invention, the heating and cooling rates are significantly improved using reduced graphene oxide as the laser absorber and heat drain. This advancement enables coherent quantum operation at temperatures up to 1400 Kelvin, surpassing the Curie temperatures of all known magnetic materials.

This invention provides opportunities for quantum sensing study of a broad range of magnetic effects, such as magnetic transitions at high temperature, thermoremanent magnetism, and magnetic shape memory effects.

In one embodiment, the nanodiamonds containing NV centers are dispersed on reduced graphene oxide film. Then, the specimen is put in vacuum chamber. Next, green laser is used to polarize and readout NV spins, and microwave is employed to manipulate the spin states of NV spins. The polarization and readout are conducted at room temperature while spin manipulation at high temperatures. Heating nanodiamond is based on the NIR light to heat conversion realized by reduced graphene oxide. The cooling is based on the good thermal conductivity of reduced graphene oxide. The fast heating and cooling beat the spin relaxation effect during heating and cooling process and thus enables spin contrast up to 1400K.

To read out spin states before spin relaxation to thermal equilibrium states, fast heating and cooling rates are essential. For achieving such fast heating and cooling rates, a substrate with high photon-thermal conversion efficiency and high heat conductivity is required.

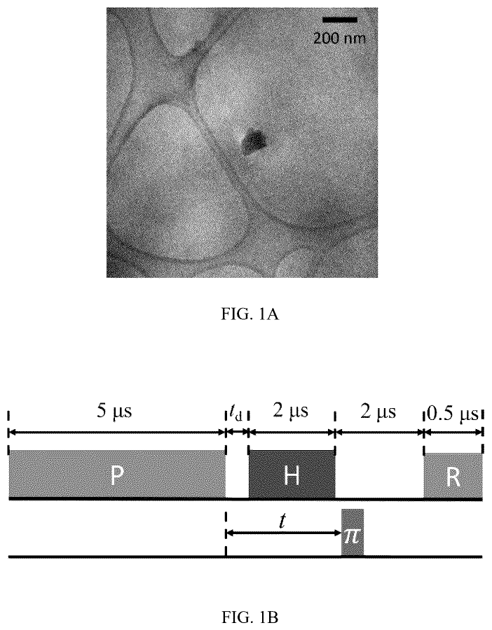

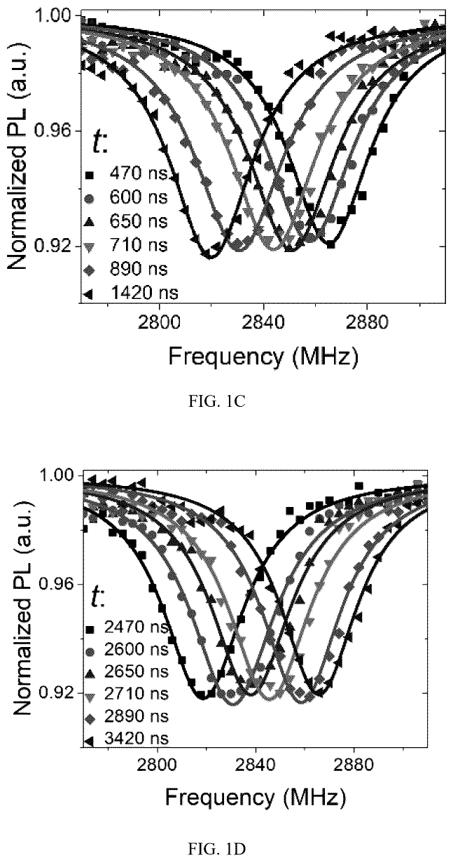

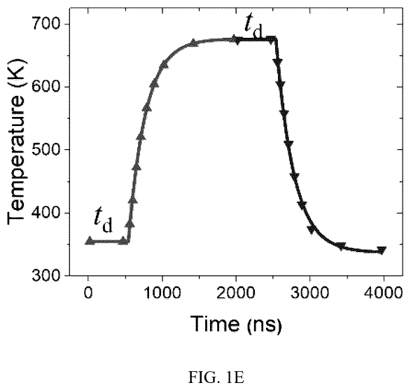

Reduced graphene oxide (rGO) dropped on transmission electron microscopy (TEM) copper grids is used, since rGO has excellent laser absorption¹¹ and heat conduction performance¹². NDs are dispersed on the rGO film as shown in FIG. 1A. The RGO used is prepared by a modified Hummer's method, as described in reference¹³. The heating and cooling dynamics are characterized using the pulse sequence shown in FIG. 1B. After optical polarization of NV center spins, the ND is heated to a stationary temperature by a pulse of 850 nm near-infrared (NIR) laser with a duration of τ_{NIR}=2000 ns, and then being cooled down to room temperature for spin readout. A microwave pulse of duration 40 ns is applied for pulsed-ODMR measurement at different times in the heating and cooling stages (0˜2000 ns and 2000˜4000 ns after the NIR pulse is turned on, respectively). The ODMR spectra of an ND on the rGO in the heating (t=0˜2000 ns≤τ_{NIR}) and cooling processes (t=2000˜4000 ns≥τ_{NIR}), respectively, are shown in FIGS. 1C and 1D. In addition, Lorentzian fitting is used to determine the zero-field splitting D of the resonance and determined the corresponding temperatures using the temperature dependence of D¹. The temperature variation is demonstrated in FIG. 1E, with the heating and cooling time scales of approximately 233 (±5) ns and 243 (±12) ns, respectively. These heating and cooling time scales are shorter by about one order of magnitude than those (about 2 μs) previously achieved on amorphous carbon films in Ar atmosphere, enabling the beating of the spin relaxation effect to achieve spin control at higher temperatures. Moreover, the laser heating efficiency of rGO exhibits excellent thermal stability in vacuum chamber during long-term cycling heating-cooling processes, overcoming the aging problem of amorphous carbon films and facilitating long-term high-temperature observation.

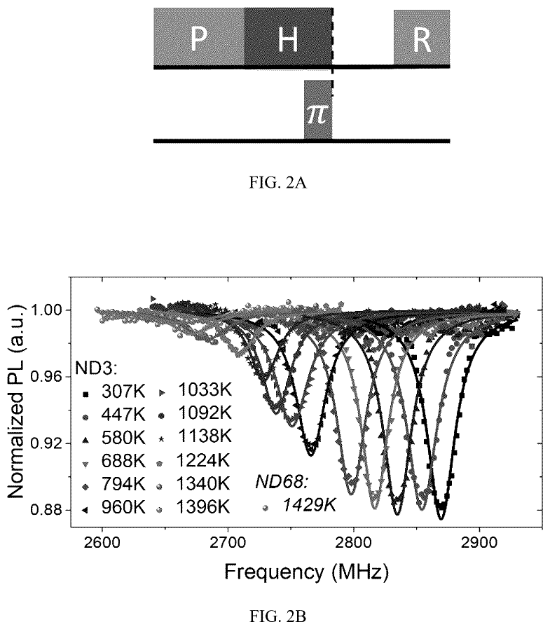

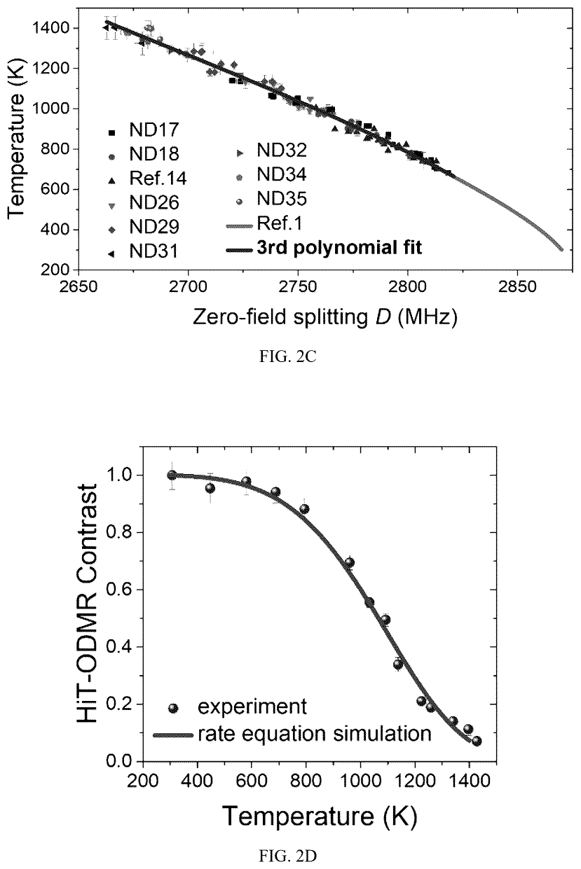

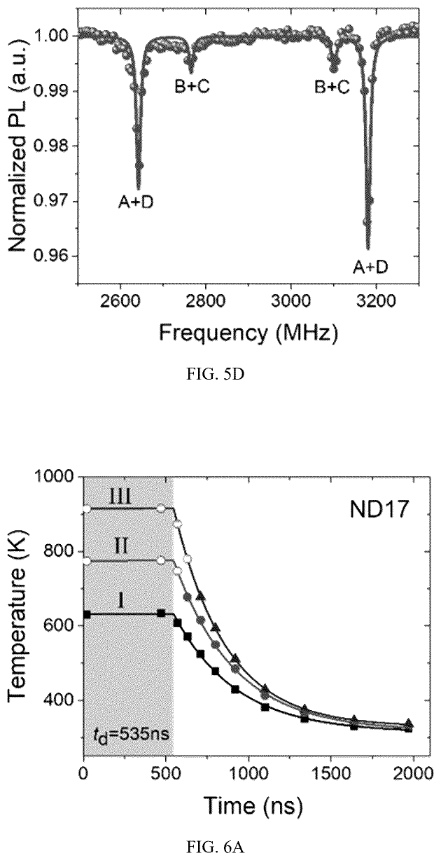

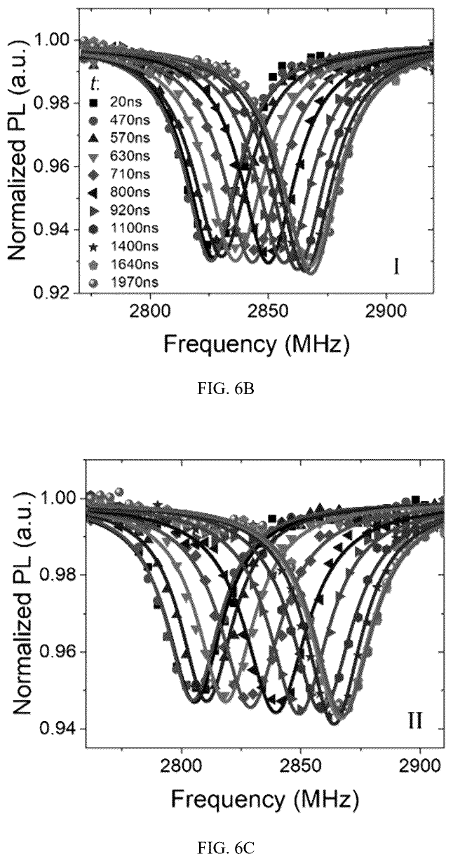

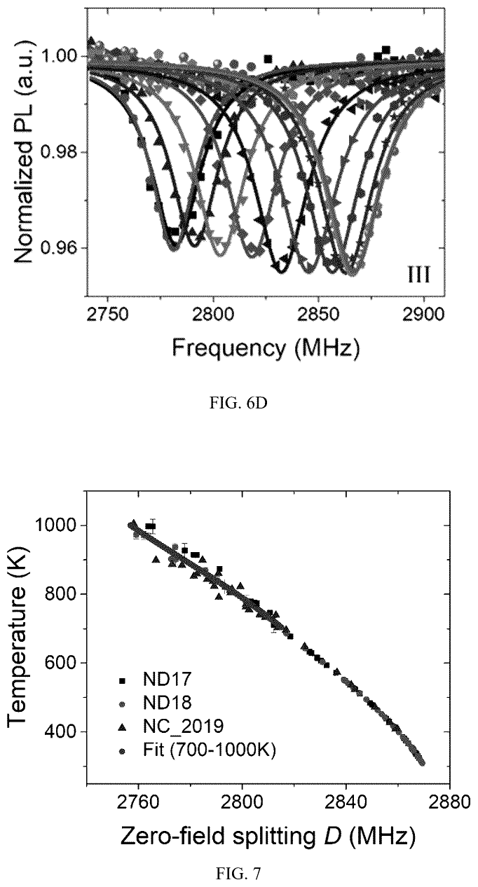

To observe high-temperature ODMR (HIT-ODMR), the NV center spins are first polarized in an ND using a green laser pulse. Then, the ND is heated using an NIR laser pulse, and at the end of the heating pulse, a microwave pulse which would flip the spins if the frequency is resonant with the spin transition is applied. After a cooling time of 2.5 μs, the spins are read out using the fluorescence during the first 500 ns of the 532 nm laser pulse. FIG. 2B shows the ODMR spectra measured with various NIR laser powers for two typical NDs (ND3 and ND 68). Herein, the ODMR contrast decreases with increasing temperature. Nonetheless, the ODMR is still well observable at temperature up to about 1429 (±11) K. The temperature dependence of the zero-field splitting D measured for eight NDs is shown in FIG. 2C. The D-T relationship in Ref. 1 is used to determine the temperature at the end of the heating pulse if D>2815 MHZ (corresponding to T<700 K). The temperature >700 K is determined by extrapolation of the cooling curve assumed to be an exponential function of cooling time. The D-T relationship for 2760 MHz≤D≤2815 MHz is first calibrated and then used for following calibration for 2700 MHZ≤D≤2760 MHz. Next, the calibrated results are used for calibration of D-T relationship for 2663 MHZ≤D≤2700 MHZ. The step-by-step calibration reduces the error of extrapolation for temperatures far away from the range where D-T relation is known. The D-T relationship for D≤2815 MHz is well fitted by T=596119.63692−654.12004D+0.24138D²−2.98934×10⁻⁵ D³, as shown in FIGS. 6-10. The reduction of contrast at high temperature as shown in FIG. 2D can be ascribed to spin relaxation during heating and cooling processes, indicated by the good agreement between the measured contrast and the numerical simulation using a temperature-dependent spin relaxation rate.

Spin relaxation is the main factor that limits the HiT-ODMR contrast and the ultimate constraint of the spin coherence time, which in turn determines the magnetometry sensitivity. The two main mechanisms of spin relaxation are cross-relaxation and spin-lattice relaxation. Cross-relaxation relies on the degeneracy of spin transition frequencies¹⁵, while spin-lattice relaxation is temperature dependent.

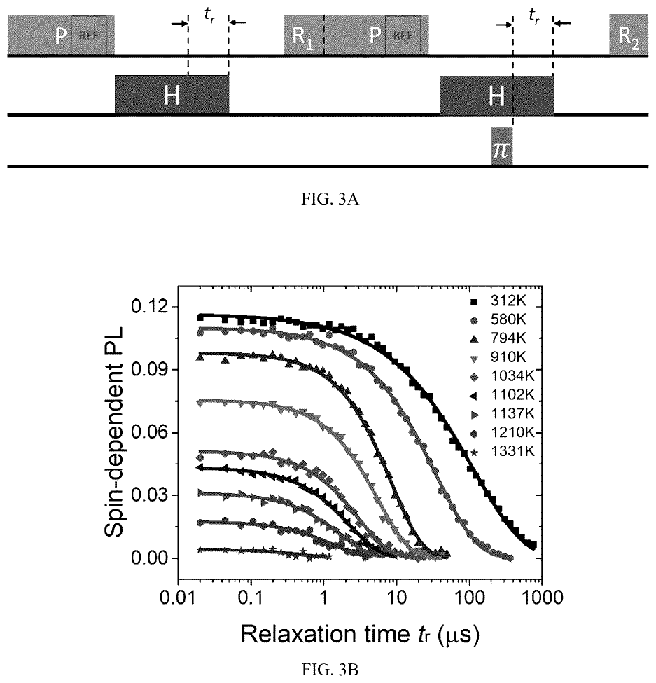

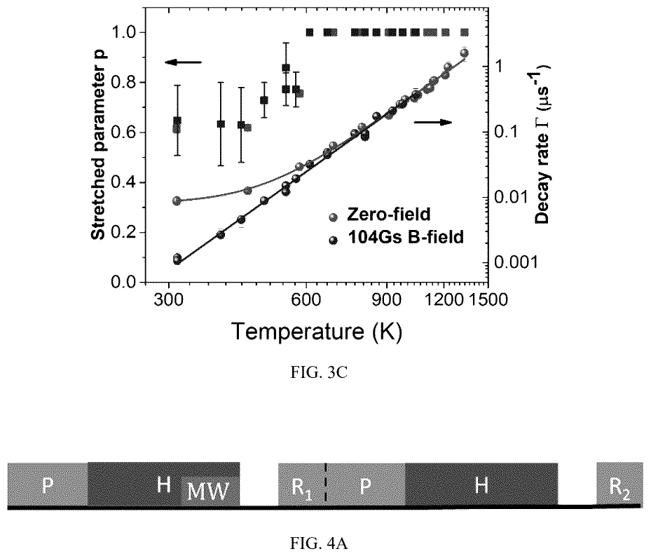

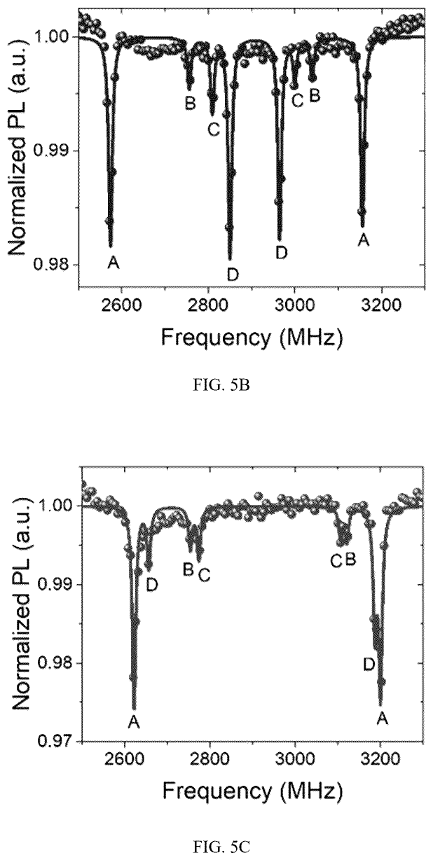

A two-unit pulse sequence shown in FIG. 3A is adopted to measure the spin relaxation rate at high temperature. Plots of the spin-polarization signal (under zero magnetic field) as a function of relaxation time for various temperatures are shown in FIG. 3B. The room-temperature relaxation time is 120 μs and could be elongated to 930 μs by applying a Magnetic field of 104 Gauss which lift the degeneracy of 4 orientations NV spins, as shown in FIG. 3C and FIG. 5. This degeneracy-dependence suggests the existence of cross-relaxation in the ND, which may occur through spin diffusion¹⁶ and polarization transfer to non-NV spins on the surface of the ND. In the range of 300-600K, the relaxation curves are fitted by a stretched exponential decay function y=Ae^{-(t/T}^{₁}⁾^{^{p}} with the stretching parameter p being about 0.6 near room temperature and increased to 1 as temperature approaching 600K, as shown in FIG. 3C. The origin of the stretched parameter deviating from 1 may arise from the inhomogeneity of spin relaxation time of NV centers with different locations in the ND^{15, 17}. With a magnetic field applied to suppress the cross-relaxation, the relaxation rates follow the T⁵ law. Above 600K, either under zero-field or a magnetic field, the relaxation curves could be well fitted by an exponential decay y=Ae^{-(t/T}^{₁}⁾, suggesting that the phonon scattering dominates the spin relaxation. The T⁵ law, arising from two-phonon Raman processes¹⁸, appears to be valid up to 1400K.

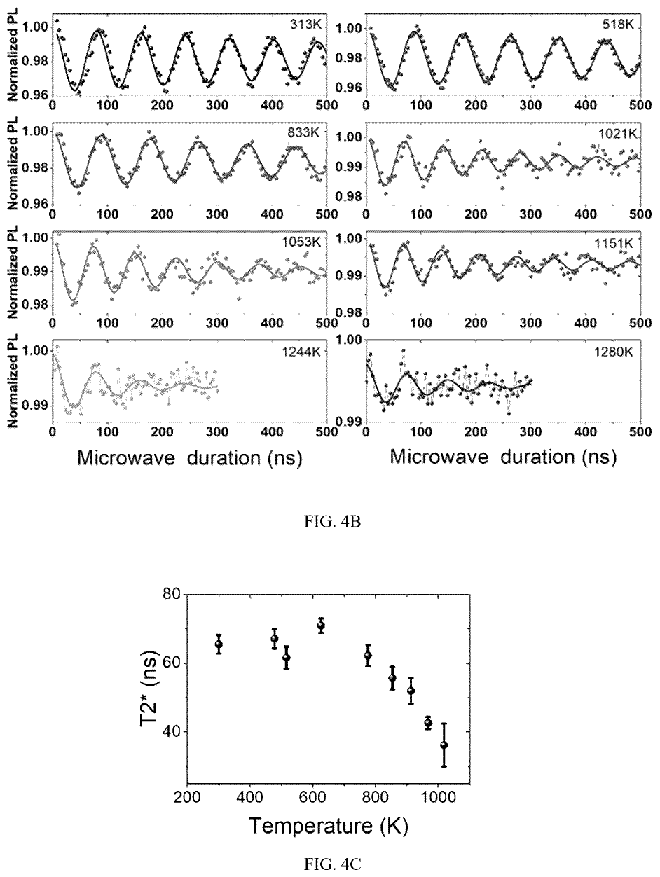

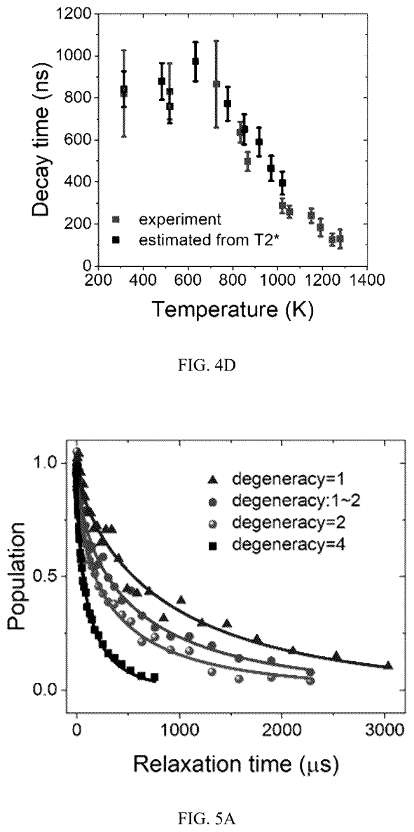

To demonstrate quantum coherence control at high temperature, Rabi oscillation of the NV center spins in NDs is performed using the pulse sequence shown in FIG. 4A. The heating NIR laser is turned on for 3.5 μs+t_{MW}. In the first unit, a microwave pulse of duration t_{MW} is applied after 3.5 μs (when the temperature reached its stationary value). The second unit without a microwave pulse is used as a reference to exclude effects not related to the spin states. FIG. 4B shows the Rabi oscillations at different temperatures. The visibility of Rabi oscillation decreases with increasing temperature, which can be attributed to the effect of spin relaxation during the heating and cooling processes. The decay time of Rabi oscillation, Tip, decreases especially when the temperature is higher than 800K as shown in FIG. 4D. This drop of Rabi oscillation lifetime can be attributed to the inhomogeneous dephasing, demonstrated by the decrease of

$${T}_{2}^{*}$$

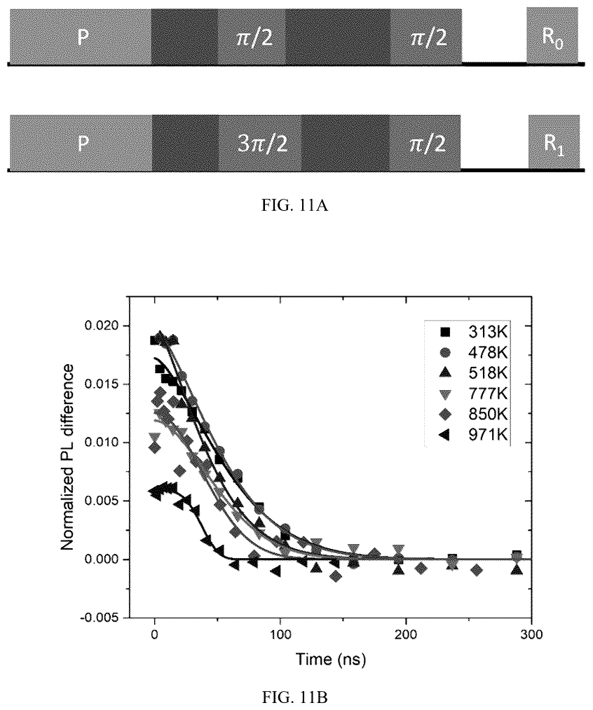

with temperature above 800K. FIG. 11 shows the pulse sequence used for

$${T}_{2}^{*}$$

measurement and typical results. The measurement involves spin polarize/readout at room temperature, while spin manipulation/evolution occurs at elevated temperatures. The value of Tip is estimated based on inhomogeneous dephasing time

$${T}_{2}^{*}$$

by numerical simulation and is in good agreement with the experiment results shown in FIG. 4D. In previous report, the

$${T}_{2}^{*}$$

of single NV center and ensemble NV centers in bulk are independent of temperature below 625K^{1, 19}. Herein, it is shown that

$${T}_{2}^{*}$$

of ensemble NV spins in nanodiamond is independent of temperature up to around 800K. The decay of

$${T}_{2}^{*}$$

time is likely caused by temperature fluctuations at higher temperature, which may result from factors such as thermal drift and laser power fluctuation. Despite the decrease of visibility and lifetime, the Rabi oscillation up to 1280K is demonstrated.

Spin resonances of NV centers at temperatures above 1400 K are observed. This high temperature is above the Curie temperatures of all known magnetic materials. With the extended operating temperature range, nanoscale resolution, multimodal sensing, and fast heating/cooling dynamics, our scheme extends the application of NV-based sensing to the study of a broad range of effects, including in-situ investigation of annealing effects on NV centers, ancient thermoremanent magnetic field recorded in rock particles, and magnetic phase transition dynamics.

Fast spin relaxation remains the primary limitation in observing and controlling quantum coherence at even higher temperatures. However, NV centers hosted in high-quality diamond structures, such as diamond nanopillars, may exhibit prolonged memory times in their nuclear spins, potentially enabling spin coherence signal above 1400K. Optimizing the heating and cooling method, including enhancements in speed, stability, and reproducibility, may extend the upper temperature limit for quantum coherence control of NV center spins.

### Materials and Methods

Samples. NDs with ensemble NV centers, averaging about 120 nm in size, are purchased from Adamas, with each ND containing about 1200 NV centers. Reduced graphene oxide is prepared using a modified Hummers' method. The aqueous rGO solution is dropped on TEM copper grid purchased from TED Pella and then dispersed NDs on rGO.

Vacuum Chamber. To avoid oxidation of samples during laser heating process, samples are protected in a vacuum chamber with vacuum level below 5*10⁻⁶ torr. The vacuum is pumped by a mechanical pump and a turbomolecular pump.

Setup. The setup is nearly same with that described in the previous work¹⁴, except that an air objective (NA=0.75) and 850 nm NIR laser is used here.

### Rate Equation Simulation for HiT-ODMR Contrast

The rate of the spin contrast can be expressed by the equation:

$$\frac{d C ( t )}{d t} = - Γ C ( t )$$

where C(t) is remaining spin contrast at time t, Γ=1/T₁ is the spin relaxation rate, which is temperature dependent, shown by the fitting formula of FIG. 3C. During heating and cooling processes, the temperature profile T(t) can be described by the following two equations, respectively.

$$Heating process : T ( t ) = - ( {T}_{s} - {T}_{o} ) exp ( - \frac{t}{{t}_{1}} ) + {T}_{s}$$

$$Cooling process : T ( t ) = ( {T}_{s} - {T}_{o} ) exp ( - \frac{t}{{t}_{1}} ) + {T}_{o}$$

Tₛ is the saturated temperature, Tₒ is environment temperature, and this the heating/cooling time scale, t₁=529 ns for ND3.

By solving the rate equation of spin contrast, following equation is obtained:

$$C ( t ) = C ( 0 ) exp ( - {\int }_{o}^{{t}_{h}} Γ dt ) exp ( - {\int }_{0}^{{t}_{c}} Γ dt )$$

tₕ is the time duration for heating and t_{c} is the time duration for cooling, and tₕ=t_{c}=2.5 us is used for HiT-ODMR experiments. Taking the temperature dependent Γ and time dependent temperature into the equation, the evolution of HiT-ODMR contrast with increase of temperature is estimated as shown in FIG. 2D.

### Temperature Calibration

Temperature calibration is provided for determining D-T relationship above 700K. In this section, the method used for D-T relationship calibration is introduced. The D-T relationship is well known from a paper on PRX¹. Thus, a part of the exponential cooling curve as temperatures below 700K is known. By extrapolation of the exponential cooling curve, the temperatures T at time points before the known cooling curve is deduced. The ZFS D is obtained from ODMR spectrum of applying π pulse at different time points. Accordingly, the D-T relationship is constructed.

It is noted that the time delay t_{d} for AOM and heat diffusion is determined before extrapolation of the cooling curve. t_{d} is determined by fitting the process with all temperatures below 700K by a nearly saturated stage followed by an exponential cooling stage.

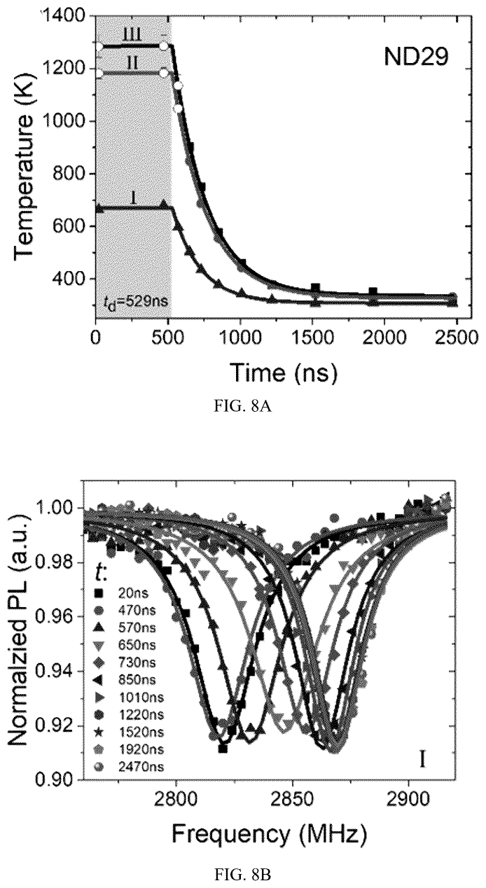

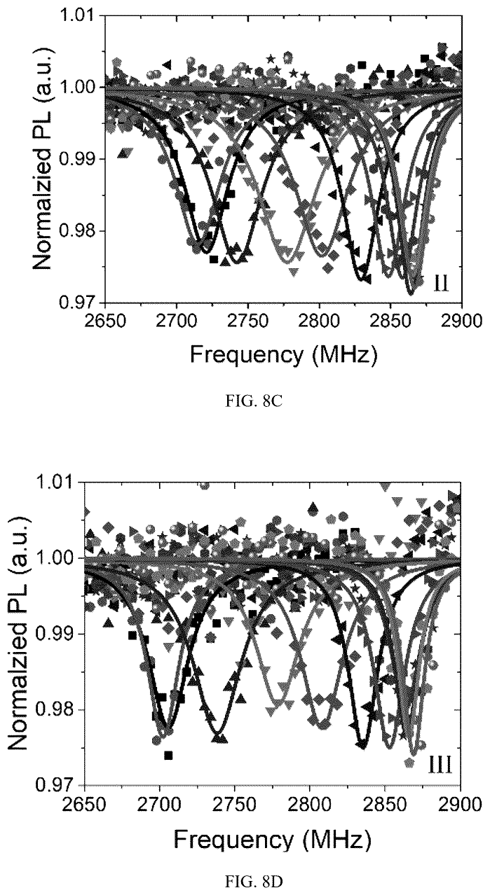

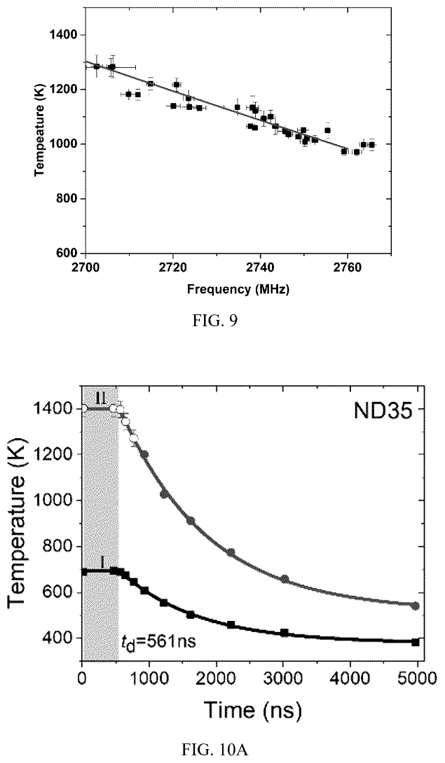

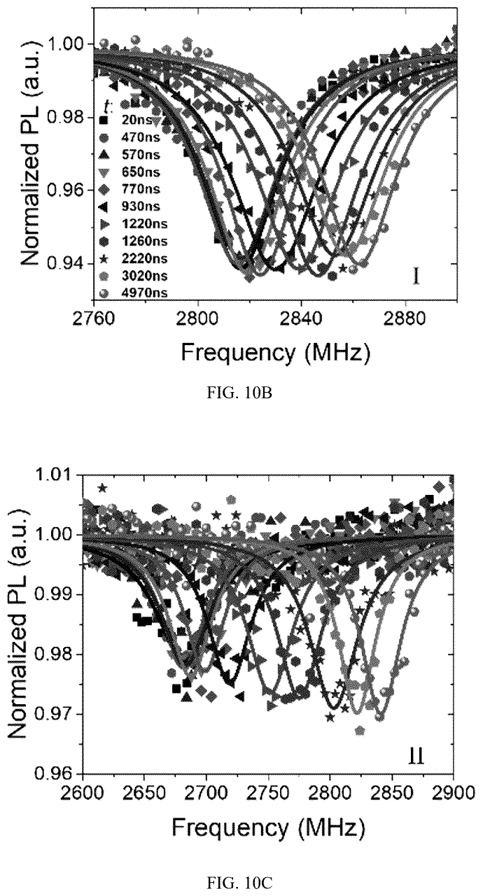

Based on the method of the embodiments of the subject invention, two nanodiamonds (ND17 and ND18) are used to calibrate the D-T relationship between 2760-2815 MHz. FIG. 6A shows the fitting curve I used to determine ta and extrapolation of cooling curves II and III to estimate the temperatures before the experimentally known region. Hollow circles indicate the estimated temperature points. FIGS. 6B-6D show the ODMR spectra obtained by applying time points shown in FIG. 6A. The calibrated D-T relationship in the range of 2760-2815 MHz based on ND17 and ND18 is shown in FIG. 7, agreeing well with results of the previous work¹⁴. Then, D-T relationship in 2760-2815 MHz is regarded as known and is used to deduce the D-T relationship in 2700-2760 MHz, as shown in FIGS. 8-9. Next, the D-T relationship in 2700-2760 MHz is also regarded as known and is used to deduce D-T relationship in 2663-2700 MHz as shown in FIG. 10. Finally, the D-T relationship from 2662 MHz to 2815 MHz is obtained and well fitted with a 3^{rd} polynomial formula. In the high temperature ODMR, spin relaxation, and Rabi oscillation section, the temperatures above 700K are determined by the formula, while temperatures below 700 K is determined by the D-T relationship from PRX¹.

### High Temperature

$${T}_{2}^{*}$$

### Measurement

As shown in FIG. 11, the sequence has two units. First, the NV center spins are polarized by 5 μs green laser, and then the nanodiamond is heated to a stable temperature with a 3.5 μs NIR laser. A π/2 pulse is applied and the temperature is kept for various times t, then another π/2 pulse is applied, followed by cooling down and readout. The second unit is similar with the first, but the first π/2 pulse is changed into a 3π/2 pulse. The difference in photocounts readout by these two units is regarded as signal and normalized by the sum of R₀ and R₁. In this way, the decay curve is obtained and fit by

$$y = A exp ( - {( t / {T}_{2}^{*} )}^{p} ) .$$

The measured

$${T}_{2}^{*}$$

of NV center spins in a nanodiamond is shown in FIG. 4C.

According to the subject invention, the

$${T}_{2}^{*}$$

is independent on temperature until 800K. Above 800K, there is decrease in

$${T}_{2}^{*}$$

with increase of temperature. Inis is likely due to the temperature fluctuation at high temperatures induced by factors such as power fluctuation and thermal drift.

### Simulation on Temperature Fluctuation Effect on Decay Time of Rabi Oscillation.

Numerical simulations are conducted to estimate the inhomogeneous dephasing effect on decay time of Rabi oscillations, assuming the inhomogeneous broadening arises a detuning 8 with Gaussian profile. The Rabi oscillation with the detuning can be expressed by following equation:

$$\int \frac{{ω}_{R}}{\sqrt{{ω}_{R}^{2} + {δ}^{2}}} cos ( \sqrt{{ω}_{R}^{2} + {δ}^{2}} t ) g ( δ ) d δ$$

where ω_{R} is Rabi frequency, t is microwave duration, and g(δ) is the Gaussian function

$$g ( δ ) = \frac{1}{\sqrt{2 π σ}} exp ( - \frac{{δ}^{2}}{2 {σ}^{2}} ) , σ = 1 / ( \sqrt{2} π {T}_{2}^{*} ) .$$

ω_{R} is obtained from the fitting decay time of experimental data of Rabi oscillation. With this method, the PL at various microwave duration is obtained and fitted with PL=A exp(−(t/T_{1ρ}))*cos(wt), in which t is the microwave duration; A, T_{1ρ}, w are fitting parameter. The obtained T_{1ρ} by this method agrees well with experimental results, indicating that inhomogeneous dephasing is the main reason for decreasing of decay time at high temperatures.

A technique to conduct quantum sensing using NV centers in diamond in a high temperature regime (up to 1400 K) is provided. Quantum sensing with nitrogen-vacancy spins in diamond at temperatures up to 1000 Kelvin has been demonstrated by polarizing and reading out the spins at room temperature and controlling them at elevated temperatures using rapid heating and cooling. Pushing the working temperature higher is desirable for applications to a broader range of materials but is limited by fast spin relaxation at high temperature in comparison with the heating and cooling rates. The heating and cooling rates are significantly improved by using reduced graphene oxide as the laser absorber and heat drain, and therefore realizing coherent quantum operation at temperatures as high as 1400 Kelvin, which is higher than the Curie temperatures of all known magnetic materials. This invention provides opportunities for quantum sensing of a broad range of magnetic effects, such as magnetic transitions at high temperature, thermal remanent magnetism, and magnetic shape memory effects.

### EXEMPLARY EMBODIMENTS

Embodiment 1. A method for fast laser heating and cooling for nano/micro diamonds) (NDs), comprising:
dispersing NDs on a reduced graphene oxide (rGO) sample; and
performing laser irradiation and thermal dissipation on the rGO sample, wherein the rGO sample is dispersed on a transmission electron microscopy (TEM) copper grid.

Embodiment 2. The method of embodiment 1, wherein each of the NDs has one or more nitrogen-vacancy (NV) centers.

Embodiment 3. The method of any preceding embodiment, further comprising placing the rGO sample in a vacuum chamber.

Embodiment 4. The method of any preceding embodiment, further comprising polarizing and reading out NV spins by green laser.

Embodiment 5. The method of any preceding embodiment, further comprising manipulating spin states of NV spins by microwave.

Embodiment 6. The method of any preceding embodiment, wherein the polarizing and reading out are conducted at room temperature.

Embodiment 7. The method of any preceding embodiment, wherein the manipulating spin states is conducted at temperatures higher than 300 K.

Embodiment 8. The method of any preceding embodiment, wherein after polarizing of the NV center spins, heating the NDs to a stationary temperature by a pulse of 850 nm near-infrared (NIR) laser with a duration of a plurality of microseconds.

Embodiment 9. The method of any preceding embodiment, further comprising applying a microwave pulse with tens of nanoseconds duration for pulsed-ODMR measurement at different times in the heating and cooling stages.

Embodiment 10. A method for fast laser heating and cooling of nano/micro-diamonds (NDs) containing nitrogen-vacancy (NV) centers, comprising:
optically polarizing NV center spins in the NDs;
applying a pulse of near-infrared (NIR) laser light having a wavelength of approximately 850 nm and a duration of about 2000 nanoseconds to heat the NDs to a stationary elevated temperature;
allowing the NDs to cool down to approximately room temperature after stopping the NIR laser pulse for spin readout;
applying a microwave pulse of approximately 40 nanoseconds during at least one of the heating stage and the cooling stage;
performing pulsed optically detected magnetic resonance (ODMR) measurements of the NDs during the heating and/or the cooling stages;
analyzing the ODMR spectra obtained; and
determining temperature-dependent zero-field splitting (D) of the resonance by Lorentzian fitting of the ODMR spectra.

Embodiment 11. The method of embodiment 10, wherein the NDs are dispersed on a reduced graphene oxide (rGO) sample.

Embodiment 12. The method of any preceding embodiment, wherein the heating stage has a time period from 0 to 2000 nanoseconds and the cooling stage has a time period from 2000 to 4000 nanoseconds after initiation of the NIR pulse.

Embodiment 13. The method of any preceding embodiment, further comprising correlating the measured zero-field splitting D to temperature based on a pre-established calibration curve of D versus temperature.

Embodiment 14. A method for determining spin coherence in a nitrogen-vacancy (NV) center in nano- or micro-diamonds under fast laser heating and cooling, comprising:
optically polarizing the NV center spins by a green laser pulse of approximately 5 microseconds;
heating the nano- or micro-diamonds to a stable elevated temperature by a near-infrared (NIR) laser pulse of approximately 3.5 microseconds;
applying a first microwave pulse of π/2 rotation to the NV center spins;
maintaining the elevated temperature for a variable delay time t;
applying a second microwave pulse of π/2 rotation;
allowing the nano- or micro-diamond to cool down;
performing optical readout of spin states; and
repeating the above steps with a modified sequence in which the first microwave pulse is replaced by a 3π/2 pulse.

Embodiment 15. The method of embodiment 14, further comprising:
determining difference in readout signals between the two sequences.

Embodiment 16. The method of embodiment 15, further comprising:
normalizing the difference by sum of the two readout signals to obtain a spin contrast signal.

Embodiment 17. The method of embodiment 16, further comprising:
generating a decay curve from the spin contrast signal as a function of the delay time t.

Embodiment 18. The method of embodiment 17, further comprising:
fitting the decay curve to an exponential function:

$$y = A exp ( - {( t / {T}_{2}^{*} )}^{p} )$$

to extract T₂*.

Embodiment 19. The method of embodiment 18, wherein the T₂* is determined to be substantially independent of temperature up to approximately 800 K.

Embodiment 20. The method of embodiment 18, wherein a decrease in T₂* is observed at temperatures above 800 K due to thermal fluctuation effects including laser power instability or thermal drift.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

### REFERENCES

1. Toyli, D. M.; Christle, D. J.; Alkauskas, A.; Buckley, B. B.; Van de Walle, C. G.; Awschalom, D. D., Measurement and Control of Single Nitrogen-Vacancy Center Spins above 600 K. Physical Review X 2012, 2 (3), 031001.
2. Wang, N.; Liu, G.-Q.; Leong, W.-H.; Zeng, H.; Feng, X.; Li, S.-H.; Dolde, F.; Fedder, H.; Wrachtrup, J.; Cui, X.-D.; Yang, S.; Li, Q.; Liu, R.-B., Magnetic Criticality Enhanced Hybrid Nanodiamond Thermometer under Ambient Conditions. Physical Review X 2018, 8 (1), 011042.
3. Liu, E.; Wang, W.; Feng, L.; Zhu, W.; Li, G.; Chen, J.; Zhang, H.; Wu, G.; Jiang, C.; Xu, H.; de Boer, F., Stable magnetostructural coupling with tunable magnetoresponsive effects in hexagonal ferromagnets. Nature Communications 2012, 3 (1), 873.
4. Kainuma, R.; Imano, Y.; Ito, W.; Sutou, Y.; Morito, H.; Okamoto, S.; Kitakami, O.; Oikawa, K.; Fujita, A.; Kanomata, T.; Ishida, K., Magnetic-field-induced shape recovery by reverse phase transformation. Nature 2006, 439 (7079), 957-960.
5. Fu, R. R.; Weiss, B. P.; Lima, E. A.; Harrison, R. J.; Bai, X.-N.; Desch, S. J.; Ebel, D. S.; Suavet, C.; Wang, H.; Glenn, D., Solar nebula magnetic fields recorded in the Semarkona meteorite. Science 2014, 346 (6213), 1089-1092.
6. Boyer, D.; Tamarat, P.; Maali, A.; Lounis, B.; Orrit, M., Photothermal imaging of nanometer-sized metal particles among scatterers. Science 2002, 297 (5584), 1160-1163.
7. Brongersma, M. L.; Halas, N. J.; Nordlander, P., Plasmon-induced hot carrier science and technology. Nature nanotechnology 2015, 10 (1), 25-34.
8. Challener, W.; Peng, C.; Itagi, A.; Karns, D.; Peng, W.; Peng, Y.; Yang, X.; Zhu, X.; Gokemeijer, N.; Hsia, Y.-T., Heat-assisted magnetic recording by a near-field transducer with efficient optical energy transfer. Nature photonics 2009, 3 (4), 220-224.
9. Kryder, M. H.; Gage, E. C.; McDaniel, T. W.; Challener, W. A.; Rottmayer, R. E.; Ju, G.; Hsia, Y.-T.; Erden, M. F., Heat assisted magnetic recording. Proceedings of the IEEE 2008, 96 (11), 1810-1835.
10. Kim, S. E.; Mujid, F.; Rai, A.; Eriksson, F.; Suh, J.; Poddar, P.; Ray, A.; Park, C.; Fransson, E.; Zhong, Y.; Muller, D. A.; Erhart, P.; Cahill, D. G.; Park, J., Extremely anisotropic van der Waals thermal conductors. Nature 2021, 597 (7878), 660-665.
11. Cui, X.; Ruan, Q.; Zhuo, X.; Xia, X.; Hu, J.; Fu, R.; Li, Y.; Wang, J.; Xu, H., Photothermal Nanomaterials: A Powerful Light-to-Heat Converter. Chemical Reviews 2023, 123 (11), 6891-6952.
12. Kim, C. B.; Lee, J.; Cho, J.; Goh, M., Thermal conductivity enhancement of reduced graphene oxide via chemical defect healing for efficient heat dissipation. Carbon 2018, 139, 386-392.
13. Lin, C.; Niu, C.; Xu, X.; Li, K.; Cai, Z.; Zhang, Y.; Wang, X.; Qu, L.; Xu, Y.; Mai, L., A facile synthesis of three dimensional graphene sponge composited with sulfur nanoparticles for flexible Li—S cathodes. Physical Chemistry Chemical Physics 2016, 18 (32), 22146-22153.14. Liu, G.-Q.; Feng, X.; Wang, N.; Li, Q.; Liu, R.-B., Coherent quantum control of nitrogen-vacancy center spins near 1000 kelvin. Nature Communications 2019, 10 (1), 1344.
15. Choi, J.; Choi, S.; Kucsko, G.; Maurer, P. C.; Shields, B. J.; Sumiya, H.; Onoda, S.; Isoya, J.; Demler, E.; Jelezko, F.; Yao, N. Y.; Lukin, M. D., Depolarization Dynamics in a Strongly Interacting Solid-State Spin Ensemble. Physical Review Letters 2017, 118 (9), 093601.
16. Jarmola, A.; Acosta, V. M.; Jensen, K.; Chemerisov, S.; Budker, D., Temperature- and Magnetic-Field-Dependent Longitudinal Spin Relaxation in Nitrogen-Vacancy Ensembles in Diamond. Physical Review Letters 2012, 108 (19), 197601.
17. Perona Martínez, F.; Nusantara, A. C.; Chipaux, M.; Padamati, S. K.; Schirhagl, R., Nanodiamond Relaxometry-Based Detection of Free-Radical Species When Produced in Chemical Reactions in Biologically Relevant Conditions. ACS Sensors 2020, 5 (12), 3862-3869.
18. Norambuena, A.; Muñoz, E.; Dinani, H. T.; Jarmola, A.; Maletinsky, P.; Budker, D.; Maze, J. R., Spin-lattice relaxation of individual solid-state spins. Physical Review B 2018, 97 (9), 094304.
19. Lin, S.; Weng, C.; Yang, Y.; Zhao, J.; Guo, Y.; Zhang, J.; Lou, L.; Zhu, W.; Wang, G., Temperature-dependent coherence properties of NV ensemble in diamond up to 600 K. Physical Review B 2021, 104 (15), 155430.

We claim:

1. A method for fast laser heating and cooling for nano/micro diamonds (NDs), comprising:
dispersing NDs on a reduced graphene oxide (rGO) sample; and
performing laser irradiation and thermal dissipation on the rGO sample, wherein the rGO sample is dispersed on a transmission electron microscopy (TEM) copper grid.

2. The method of claim 1, wherein each of the NDs has one or more nitrogen-vacancy (NV) centers.

3. The method of claim 2, further comprising placing the rGO sample in a vacuum chamber.

4. The method of claim 3, further comprising polarizing and reading out NV spins by green laser.

5. The method of claim 4, further comprising manipulating spin states of NV spins by microwave.

6. The method of claim 4, wherein the polarizing and reading out are conducted at room temperature.

7. The method of claim 5, wherein the manipulating spin states is conducted at temperatures higher than 300K.

8. The method of claim 4, wherein after polarizing of the NV center spins, heating the NDs to a stationary temperature by a pulse of 850 nm near-infrared (NIR) laser with a duration of a plurality of microseconds.

9. The method of claim 8, further comprising applying a microwave pulse with tens of nanoseconds duration for pulsed-ODMR measurement at different times in the heating and cooling stages.

10. A method for fast laser heating and cooling of nano/micro-diamonds (NDs) containing nitrogen-vacancy (NV) centers, comprising:
optically polarizing NV center spins in the NDs;
applying a pulse of near-infrared (NIR) laser light having a wavelength of approximately 850 nm and a duration of about 2000 nanoseconds to heat the NDs to a stationary elevated temperature;
allowing the NDs to cool down to approximately room temperature after stopping the NIR laser pulse for spin readout;
applying a microwave pulse of approximately 40 nanoseconds during at least one of the heating stage and the cooling stage;
performing pulsed optically detected magnetic resonance (ODMR) measurements of the NDS during the heating and/or the cooling stages;
analyzing the ODMR spectra obtained; and
determining temperature-dependent zero-field splitting (D) of the resonance by Lorentzian fitting of the ODMR spectra.

11. The method of claim 10, wherein the NDs are dispersed on a reduced graphene oxide (rGO) sample.

12. The method of claim 10, wherein the heating stage has a time period from 0 to 2000 nanoseconds and the cooling stage has a time period from 2000 to 4000 nanoseconds after initiation of the NIR pulse.

13. The method of claim 10, further comprising correlating the measured zero-field splitting D to temperature based on a pre-established calibration curve of D versus temperature.

14. A method for determining spin coherence in a nitrogen-vacancy (NV) center in nano- or micro-diamonds under fast laser heating and cooling, comprising:
optically polarizing the NV center spins by a green laser pulse of approximately 5 microseconds;
heating the nano- or micro-diamonds to a stable elevated temperature by a near-infrared (NIR) laser pulse of approximately 3.5 microseconds;
applying a first microwave pulse of π/2 rotation to the NV center spins;
maintaining the elevated temperature for a variable delay time t;
applying a second microwave pulse of π/2 rotation;
allowing the nano- or micro-diamond to cool;
performing optical readout of spin states; and
repeating the above steps with a modified sequence in which the first microwave pulse is replaced by a 3π/2 pulse.

15. The method of claim 14, further comprising:
determining a difference in readout signals between the two sequences.

16. The method of claim 15, further comprising:
normalizing the difference by sum of the two readout signals to obtain a spin contrast signal.

17. The method of claim 16, further comprising:
generating a decay curve from the spin contrast signal as a function of the delay time t.

18. The method of claim 17, further comprising:
fitting the decay curve to an exponential function:
$$y = A exp ( - {( t / {T}_{2}^{*} )}^{p} ) ,$$
to extract T₂*.

19. The method of claim 18, wherein the T₂* is determined to be substantially independent of temperature up to approximately 800 K.

20. The method of claim 18, wherein a decrease in T₂* is observed at temperatures above 800 K due to thermal fluctuation effects including laser power instability or thermal drift.
